(19) United States
(12) Patent Application Publication
(10) Pub. No.: US 2011/0014785 A1
(43) Pub. Date: Jan. 20, 2011

(54) Method for manufacturing semiconductor device, and semiconductor manufacturing apparatus used in said method

(75) Inventor: Yuji Shimizu, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki-shi (JP)

(21) Appl. No.: 12/801,858

(22) Filed: Jun. 29, 2010

(30) Foreign Application Priority Data
Jul. 15, 2009 (JP) 2009-166657

(51) Int. Cl. H01L 21/60; C23C 16/458

(52) U.S. Cl. 438/613; 118/728; 257/E21.508

(57) ABSTRACT

This method includes an electrode pad forming process for forming an electrode pad on a substrate, a solder bump forming process for forming a solder bump on the electrode pad, at least part of the surface of the solder bump being covered with a flux, and an oxygen exposure process for supplying an oxygen gas having reactive properties, such as an ozone (O₃) gas, to the solder bump.

This application is based on Japanese patent application No. 2009-166657, the content of which is incorporated hereinto by reference.

### BACKGROUND

1. Technical Field

The present invention relates to a method for manufacturing a semiconductor device, and a semiconductor manufacturing apparatus used in the method.

2. Related Art

As portable electronic devices have been becoming smaller and achieving higher speeds in recent years, flip-chip mounting technique is now widely used to connect semiconductor chips to interconnect substrates not by wire bonding but with solder bumps. In the flip-chip mounting, interconnect lengths can be made shorter, and higher-speed transmission characteristics can be achieved than in a case where connections are performed by wire bonding. Also, smaller packages can be realized.

As such a method for forming a solder bump, Japanese Laid-Open Patent Publication No. 2004-6818 discloses a method by which a solder paste is applied by a printing technique, and then hydrogen plasma is supplied during reflow soldering to volatilize the flux. By this method, excellent soldering can be performed.

Japanese Laid-Open Patent Publication Nos. 2007-266054 and 2008-41980 also disclose methods by which hydrogen plasma is used to remove the oxide film formed on each solder bump surface.

Flux is used to remove oxide in solder prior to melting of the solder and prevent reoxidation of the solder during the melting of the solder. However, it has become apparent from findings by the inventor that flux has following problems. Flux might cause a thermal alteration (a chemical reaction) during a heat treatment for melting solder. Particularly, where the compounding ratio of Pb in solder formed by mixing lead (Pb) with tin (Sn) is 95% or higher, solder melting temperature becomes as high as 300° C. or even higher. As a result, a chemical reaction of flux easily occurs. The chemically-altered flux is not easily dissolved with an organic solvent. Therefore, even if a removing process using an organic solvent is performed later, flux remains on a surface of each solder bump.

When a semiconductor element formed on a substrate with remaining flux on surfaces of solder bumps is mounted on an interconnect substrate, electric contact failures are caused between the solder bumps of the interconnect substrate and the solder bumps of the semiconductor element. As a result, yield in manufacturing the semiconductor device is lowered.

By any of the conventional techniques disclosed in Japanese Laid-Open Patent Publication Nos. 2004-6818, 2007-266054, and 2008-41980, however, the chemically-altered flux cannot be removed.

### SUMMARY

In one embodiment, there is provided a method for manufacturing a semiconductor device including forming an electrode pad over a substrate, forming a solder bump over the electrode pad, at least part of a surface of the solder bump being covered with flux, and exposing the solder bump to oxygen gas reactive therewith.

In another embodiment, there is provided a semiconductor manufacturing apparatus including a stage over which a substrate is placed, an electrode pad being formed over the substrate, flux-containing solder being applied onto the electrode pad, a heating unit that melts the solder applied onto the electrode pad, and an oxygen supply unit that supplies oxygen gas reactive with a solder bump formed through melting of the solder.

According to the present invention, the reactive oxygen gas is supplied after the solder bump is formed by melting the solder. Therefore, the flux chemically altered through a heating treatment for melting the solder can be removed from the solder bump. Accordingly, a solder bump of an interconnect substrate and the solder bump of the semiconductor element can be properly connected.

According to the present invention, a solder bump of an interconnect substrate and the solder bump of the semiconductor element can be properly connected. Thus, yield in manufacturing the semiconductor device can be made higher.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A through 1H are schematic views for explaining a method for manufacturing a semiconductor device according to an embodiment;

FIG. 2 is a schematic view of an apparatus used in the method for manufacturing a semiconductor device of the embodiment;

FIGS. 3A through 3I are schematic views for explaining a method for manufacturing a semiconductor device according to a first modification of the embodiment;

FIGS. 4A through 4C are schematic views for explaining a method for manufacturing a semiconductor device according to a second embodiment of the embodiment;

FIG. 5 is a graph showing results of examples;

FIG. 6 is a graph showing results of examples; and

FIGS. 7A through 7D are schematic views for explaining a method for manufacturing a semiconductor device as a comparative example.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Embodiments according to the present invention are described hereinbelow with reference to the drawings. In all the drawings, equivalent components are denoted by the same reference numerals, and their redundant explanations will not be repeated.

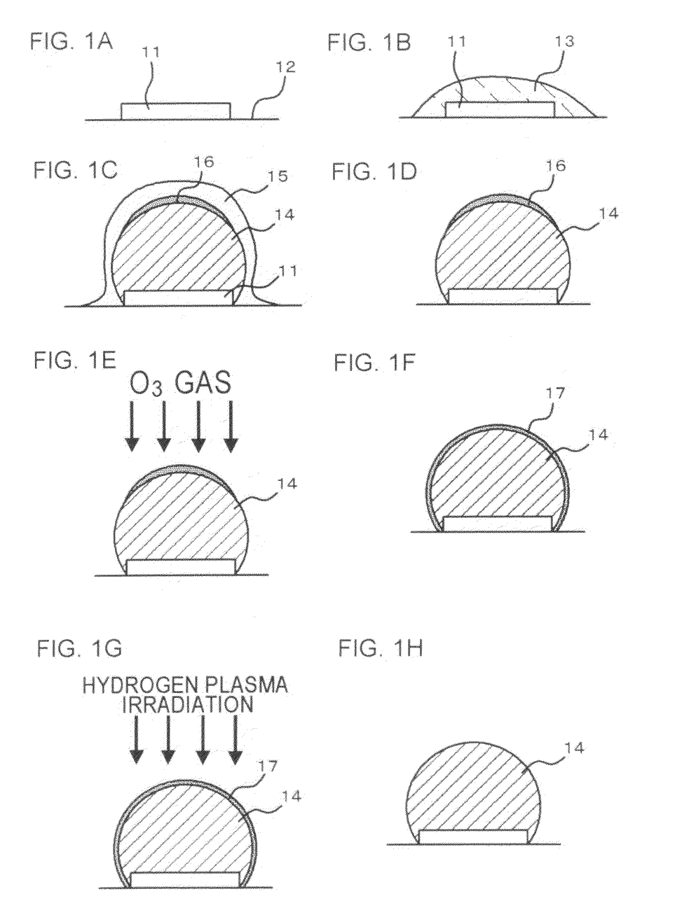

FIGS. 1A through 1H are schematic views illustrating a method for manufacturing a semiconductor device of this embodiment. This embodiment includes: an electrode pad forming process (FIG. 1A) for forming an electrode pad 11 on a substrate 12; a solder bump forming process (FIG. 1C) for forming a solder bump 14 on the electrode pad 11, the solder bump 14 having its surface at least partially covered with flux 15; and an oxygen exposure process (FIG. 1E) for supplying oxygen gas reactive with the solder bump 14, such as ozone (O₃) gas.

Hereinafter, this embodiment is described in detail. First, a solder paste 13 made, by mixing minute solder particles with flux is applied onto the electrode pad 11 (FIG. 1A) on the substrate 12 (FIG. 1B).

To apply the solder paste 13, there is a way to print the solder paste on the electrode pad 11. Specifically, the solder paste is imprinted after patterning by applying a resist film onto the substrate 12. In other cases, the solder paste 13 is imprinted on a metal mask after pressing the metal mask onto a semiconductor element.

A heating treatment is then performed at a temperature equal to or higher than the solder melting temperature. After the heating treatment, the solder paste 13 is melted and turned into the spherical solder bump 14. At this point, the flux 15 contained in the solder paste 13 has served to remove oxide from the solder prior to the solder melting and prevent reoxidation of the solder during the solder melting. The flux 15 then remains on the surface of the solder bump 14 (FIG. 1C).

Here, part of the flux causes a chemical reaction such as a carbonization reaction or an oxidation reaction during the solder melting. For example, it is well known that abietic acid, which is a kind of flux component, turns into neoabietic acid when heated to 300° C. Accordingly, chemically-altered flux 16 also remains on the surface of the solder bump 14.

The flux 15 remaining on the surface of the solder bump 14 is then removed. To remove the flux 15, the flux 15 is dissolved with an organic solvent such as ethylene glycol, for example. At this point, the chemically-altered flux 16 is not easily dissolved with the organic solvent. Therefore, the chemically-altered flux 16 remains on the solder bump surface after the treatment with the organic solvent (FIG. 1D).

The ozone gas (O₃ gas) is then supplied for a certain period of time (FIG. 1E). Preferably, the O₃ gas is supplied for 10 seconds or longer, more preferably, for 20 seconds or longer, or even more preferably, for 30 seconds or longer. With this treatment, the chemically-altered flux 16 on the surface of the solder bump 14 vaporizes as gas (COₓ) such as carbon dioxide gas, and is thus removed. By setting the O₃ gas exposure time to 40 seconds or shorter, the flux 16 is efficiently removed and throughput degradation can be prevented.

Note that the solder bump 14 may be treated with oxygen-containing plasma, instead of the O₃ gas exposure.

At this point, an oxide film 17 might be formed on the surface of the solder bump 14 due to the O₃ gas exposure (FIG. 1F). After the O₃ gas exposure, the solder bump 14 is preferably exposed to reduction gas such as hydrogen (a reduction gas exposure process). For example, a hydrogen plasma treatment can be performed on the solder bump 14 for a certain period of time (a hydrogen plasma irradiation process). In this manner, the solder bump 14 is irradiated with hydrogen plasma (FIG. 1G), and the surface of the solder bump 14 is reduced. As a result, the oxide film 17 is removed, and the formation of the solder bump 14 is completed (FIG. 1H).

Through the above processes, the solder bumps are formed on the semiconductor element and an interconnect substrate, and those solder bumps are connected. After that, predetermined processes are performed to complete the semiconductor device.

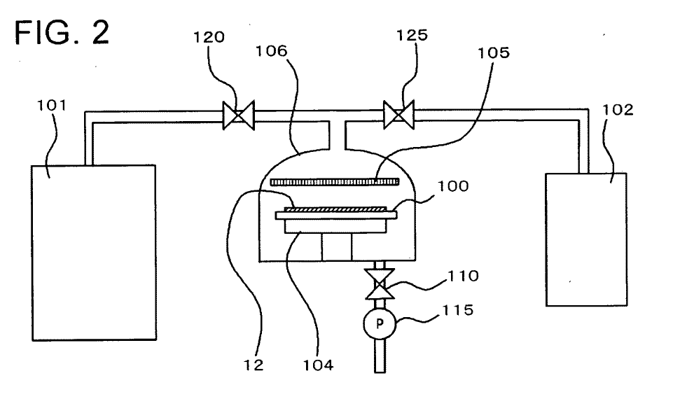

FIG. 2 is a schematic view of an apparatus used in this embodiment. This apparatus includes: a stage 100 on which the substrate 12 having the solder paste 13 containing the flux applied thereto is placed; a heater (a heating unit) 104 that melts the solder paste 13 applied onto the electrode pad 11; and an ozone gas generating unit (an oxygen supply unit) 101 that supplies the ozone gas to the solder bump 14 formed through the melting of the solder paste 13. A gas amount generated from the ozone gas generating unit 101 is adjusted by a valve 120 before the gas is supplied to a chamber 106.

This apparatus may further include a hydrogen gas supply unit 102 (a reduction gas supply unit) that supplies hydrogen gas, and a plasma generating unit 105. A hydrogen gas amount generated from the hydrogen gas supply unit 102 is adjusted by a valve 125 before the hydrogen gas is supplied to the chamber 106. The plasma generating unit 105 generates the hydrogen plasma with the hydrogen gas supplied from the hydrogen gas supply unit 102. In this manner, the oxide film 17 formed on the solder bump 14 due to the O₃ gas is subjected to the hydrogen plasma treatment, and as a result, the oxide film 17 is removed through a reduction. The gas in the chamber 106 is then evacuated from the chamber 106 by an exhaust pump 115. An exhaust valve 110 adjusts an exhausted gas amount from the chamber 106.

In the apparatus illustrated in FIG. 2, the single chamber 106 houses the heater 104 and the plasma generating unit 105 that forms the plasma through application of high-frequency electrical power, to introduce the O₃ gas and the hydrogen gas into the chamber 106. When the hydrogen gas is introduced, the high-frequency electrical power is applied to the plasma generating unit 105 to generate the hydrogen plasma in the chamber 106. Accordingly, it is possible to sequentially perform the series of processes: the solder reflow process, the process for removing the chemically-altered flux 16 from the surface of the solder bump 14 through the O₃ gas exposure, and the process for removing the oxide film 17 from the surface of the solder bump 14 through the hydrogen plasma irradiation. Instead of the O₃ gas, oxygen-containing plasma may be used for the process for removing the chemically-altered flux 16.

Next, a method for manufacturing a semiconductor device of this embodiment using the apparatus illustrated in FIG. 2 is described. First, the substrate 12 having the solder paste 13 applied onto the electrode pad 11 (FIG. 1B) is placed on the stage 100 in the chamber 106 shown in FIG. 2. The substrate 12 is then heated by the heater 104, and the solder paste 13 is melted to form the solder bump 14 (FIG. 1C). After the formation of the solder bump 14, the substrate 12 is brought out from the chamber 106. Although the substrate 12 is heated by the heater 104 provided in the chamber 106 in this embodiment, another type of heating device may be used. Flux cleaning is then performed (FIG. 1D) with a cleaning apparatus that is independent of the apparatus illustrated in FIG. 2. In the flux cleaning, an organic solvent such as ethylene glycol is used. The substrate 12 after the flux cleaning is again placed on the stage 100 in the chamber 106, and is exposed to the O₃ gas for the certain period of time (FIG. 1E). This process may be performed with oxygen-containing plasma, oxygen plasma and so on, instead of the O₃ gas. The oxygen plasma can be generated by supplying the oxygen gas or the ozone gas from the oxygen supply unit 101 to the chamber 106, and applying the high-frequency electrical power to the plasma generating unit 105. After that, the hydrogen gas is supplied from the hydrogen gas supply unit 102 to the chamber 106, and the high-frequency electrical power is applied to the plasma generating unit 105 to generate the hydrogen plasma (FIG. 1G). The O₃ gas treatment and the hydrogen plasma treatment are performed under the processing conditions used in the method illustrated in FIGS. 1A through 1H.

Functions and effects of this embodiment are now described with reference to FIGS. 1A through 1H. By the method according to this embodiment, the solder paste 13 is melted to form the solder bump 14, and then the O₃ gas is supplied. With this treatment, the flux 16 chemically altered due to the heating treatment performed to melt the solder paste 13 is volatilized as the gas (CO_{X}) such as a carbon dioxide gas, and is removed from the solder bump 14.

By the method according to this embodiment, the oxide film 17 on the surface of the solder bump 14 formed by the O₃ gas treatment can be reduced and removed by the hydrogen plasma treatment performed after the O₃ gas treatment. Accordingly, the solder bumps of the interconnect substrate and the solder bumps on the semiconductor element can be properly connected.

In this embodiment, the altered flux is removed with the O₃ gas, and then the oxidized surface of the solder bump 14 is reduced by the hydrogen plasma treatment. Some part of the altered flux that is not removed with the O₃ gas is more efficiently removed through the following operations. Specifically, the altered flux is once transformed into the oxide through the oxidization by the O₃ gas. The hydrogen plasma treatment is then performed to combine the oxide with hydrogen and remove the oxide from the solder bump 14. In this manner, the altered flux can be effectively removed. By the above operations, the altered flux can be more effectively removed in this embodiment than in a case where the altered flux is removed only with an O₃ gas or by a hydrogen plasma treatment.

Although embodiments of the present invention have been described so far with reference to the drawings, they are merely examples of the present invention, and various other configurations may be employed.

### [First Modification]

For example, although the solder paste 13 is applied onto the electrode pad 11 in the above embodiment, a solder bump may also be formed by performing plating on an electrode pad in the present invention.

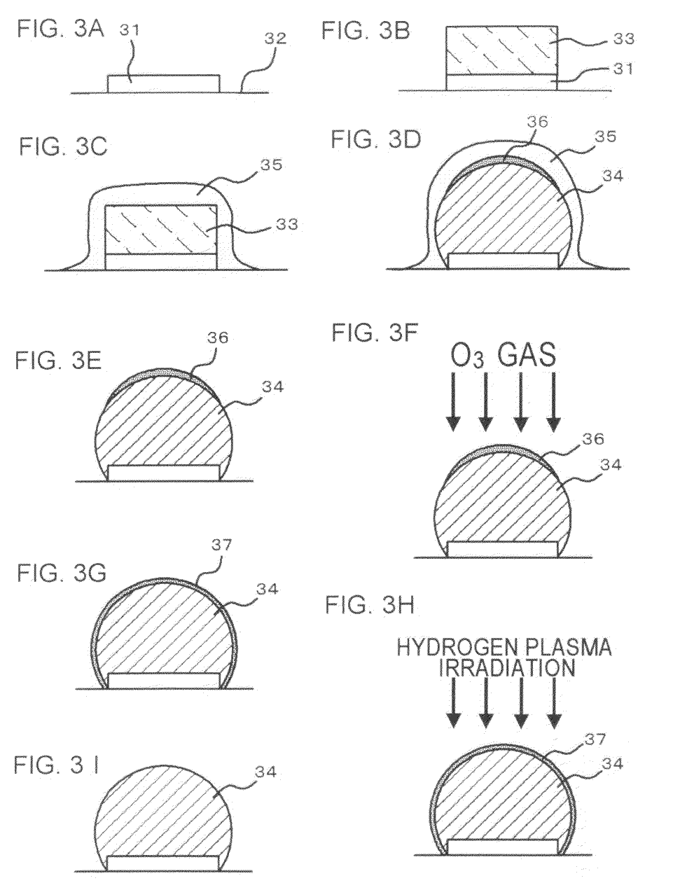

FIGS. 3A through 3I are drawings for explaining this first modification. First, plating is performed on a substrate 32 having an electrode pad 31 formed thereon (FIG. 3A) with the use of a patterning film such as a photoresist. As a result, a solder-plate film 33 is formed on the electrode pad 31 (FIG. 3B).

After the photoresist as the patterning film is removed, flux 35 is applied so as to cover the electrode pad 31 and the solder-plate film 33 (FIG. 3C).

A heating treatment is then performed to melt the solder-plate film 33 and form a solder bump 34. At this point, part of the flux 35 is chemically altered, and the chemically-altered flux 36 remains on the surface of the solder bump 34 (FIG. 3D).

The flux 35 is then removed with the use of an organic solvent such as ethylene glycol (FIG. 3E). At this point, the chemically-altered flux 36 is not easily dissolved with the organic solvent. Therefore, the chemically-altered flux 36 remains on the surface of the solder bump 34 after the treatment with the organic solvent.

O₃ gas is then supplied for a certain period of time to oxide the chemically-altered flux 36 and volatilize the chemically-altered flux 36 as gas (COₓ) such as carbon dioxide gas (FIG. 3F).

To remove an oxide film 37 (FIG. 3G) formed on the surface of the solder bump 34 due to the O₃ gas exposure, a hydrogen plasma irradiation process is performed (FIG. 3H). Through the hydrogen plasma irradiation process for a certain period of time, the oxide film 37 is removed from the surface of the solder bump 34, and the formation of the solder bump 34 is completed (FIG. 3I).

As described above, the present invention can adopt the solder bump forming method with either the printing method or the plating method. Accordingly, yield loss in manufacturing the semiconductor device can be prevented.

### [Second Modification]

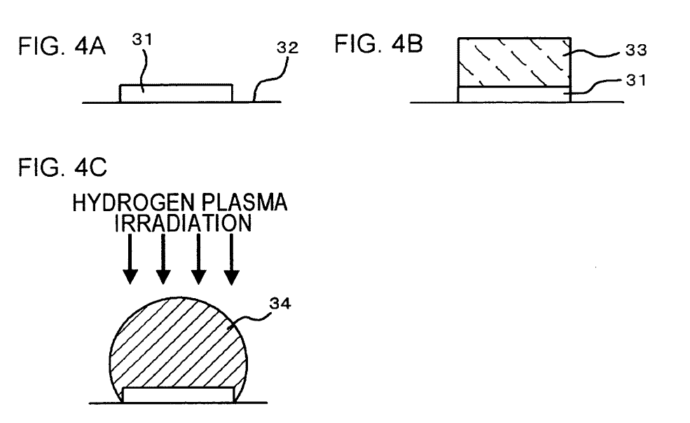

Although the flux 35 is used in the above described modification, the flux 35 may not be used. Referring now to FIG. 4A through 4C, a second modification is described in detail. In FIGS. 4A through 4C, the processes to form the solder-plate film 33 on the substrate 32 having the electrode pad 31 formed thereon (FIG. 4A) by performing plating with the use of a patterning film such as a photoresist are the same as those of the above modification (FIG. 4B). In FIG. 4C, the solder-plate film 33 is heated with concurrently irradiated with hydrogen plasma to form the solder bump 34. Since the flux 35 is not used in this second modification, an O₃ gas exposure is unnecessary and the number of manufacturing processes can be reduced. Furthermore, since the chemically-altered flux 36 that is hard to remove is not generated, the solder bumps of the interconnect substrate and the solder bumps of the semiconductor substrate can be properly connected.

Hereinafter, shown are the results of experiments carried out to verify the effects of the present invention.

In the experiments, the solder bump 14 was formed on the substrate 12 through the method illustrated in FIGS. 1A through 1H. In the process illustrated in FIG. 1F, the O₃ gas exposure time was varied. Other configurations were the same as those of the first embodiment. CH₃ ions were observed by TOF-SIMS (time-of-flight secondary ion mass spectrometry), and the observed CH₃ ions were counted to examine an amount of the flux adhering to the surface of the solder bump 14. Also, the obtained solder bump 14 was connected to a solder bump of an interconnect substrate, and an incident rate of defective connections was measured. The incident rate of defective connections was obtained through conduction tests with the solder bumps.

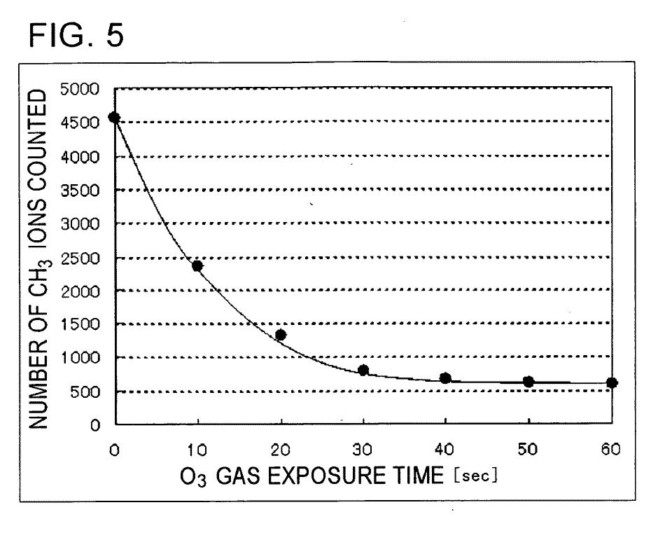

FIG. 5 shows the results of the experiments carried out with the O₃ gas exposure time varied as 0, 10, 20, 30, 40, 50, and 60 seconds.

In FIG. 5, the abscissa axis indicates the O₃ gas exposure time, and the ordinate axis indicates the number of CH₃ ions counted by the TOF-SIMS. As can be seen from FIG. 5, in the cases where the O₃ gas exposure is performed for 10 seconds or longer, the amount of the flux remaining on the surface of the solder bump 14 can be reduced to approximately ½ or less of the amount observed in the case where the O₃ gas exposure is not performed (where the O₃ gas exposure time is 0 seconds). In addition, the amount of the flux remaining on the surface of the solder bump 14 stays almost the same in the cases where the O₃ gas exposure time is 40 seconds or longer, so that it has become apparent that 40 seconds is enough as the O₃ gas exposure time. If the O₃ gas exposure time is too long, the oxidation of the surface of the solder bump 14 may progress. Therefore, the O₃ gas exposure time should be 40 seconds or shorter.

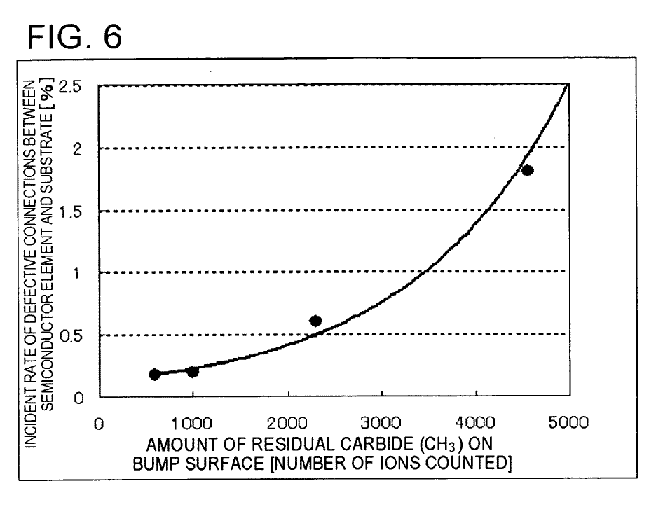

FIG. 6 shows the incident rate of defective connections caused when the solder bump 14 formed on the substrate 12 is connected to the solder bump of the interconnect substrate with the O₃ gas exposure time being varied. In FIG. 6, the abscissa axis indicates the number of CH₃ ions counted by the TOF-SIMS, and the ordinate axis indicates the incident rate of defective connections. In the case where the O₃ gas is not supplied, the incident rate of defective connections is 1.5% or higher. In the present invention involving the O₃ gas supply, the incident rate of defective connections becomes lower from 0.6% to 0.3% to 0.2%, as the O₃ gas exposure time is set longer from 10 to 20 to 30 seconds. Particularly, it has become apparent that the incident rate of defective connections can be made remarkably reduced when the O₃ gas exposure time is 30 seconds or longer.

As described above, the O₃ gas exposure time should be 10 seconds or longer to restrain defective connections. Preferably, the O₃ gas exposure time should be 20 seconds or longer, or more preferably, 30 seconds or longer but not longer than 40 seconds.

### Comparative Example

Lastly, an example according to the present invention is described with referring a comparative example.

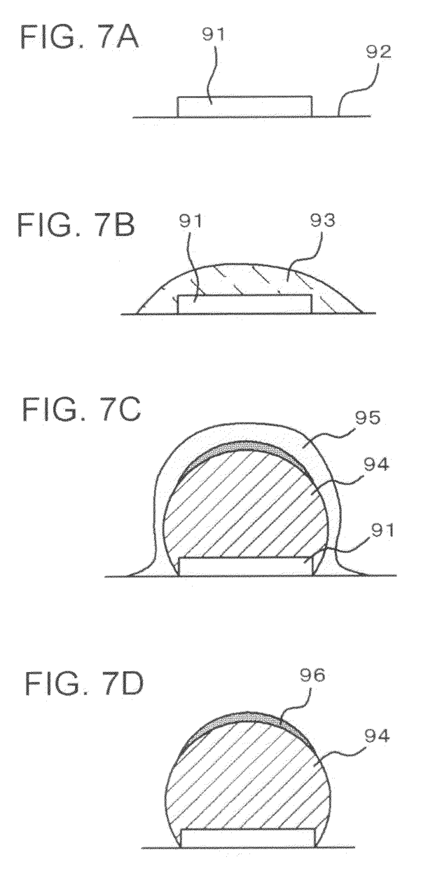

FIGS. 7A through 7D illustrate the comparative example of a method for forming a solder bump that is a conductive terminal. First, an electrode pad 91 is formed on a substrate 92 (FIG. 7A), and then a solder paste 93 is applied onto the electrode pad 91 (FIG. 7B). The solder paste 93 contains flux containing rosin as main component.

The solder paste 93 applied onto the electrode pad 91 is then subjected to a heating treatment at a temperature equal to or higher than the solder melting temperature. In this manner, the electrode pad 91 and the solder are chemically bound, and a solder bump 94 is formed on the electrode pad 91 (FIG. 7C).

Here, the flux 95 is used to remove the oxide from the solder prior to the melting of the solder and prevent reoxidation of the solder during the melting of the solder. Therefore, the flux 95 becomes unnecessary after the solder bump 94 is formed. If the flux 95 remains on the solder bump 94, defective connections may be caused between the solder bump 94 and a solder bump formed on another substrate or the like at the time of a connection to another member. Therefore, the flux 95 remaining on the surface of the solder bump 94 is normally removed after the formation of the solder bump 94. As a conventional method of removing the flux 95, there is a method with a removing process using an organic solvent and a rinsing process using DIW (De-Ionized Water) performed subsequently thereto, for example.

In such a case, once a chemically-altered (thermally-altered) flux 96 is formed on the solder bump 94 (FIG. 7D), the chemically-altered flux 96 cannot be removed by cleaning with an organic solvent performed immediately after the formation of the chemically-altered flux 96.

In the present invention, on the other hand, the thermally-altered flux 96 formed as described above is exposed to the reactive oxygen gas. Accordingly, the thermally-altered flux 96 can be effectively removed.

Although the O₃ gas is used in the above described embodiment, oxygen plasma may be used instead of the O₃ gas. By introducing oxygen gas into a gas chamber and then making the oxygen gas plasma activated, the solder bump can be irradiated with oxygen plasma. In addition, the hydrogen gas is used as the reduction gas in the above embodiment, but any gas other than the hydrogen gas may be used, as long as the gas has reduction characteristics.

It is apparent that the present invention is not limited to the above embodiment, and may be modified and changed without departing from the scope and spirit of the invention.

What is claimed is:

1. A method for manufacturing a semiconductor device, comprising:
forming an electrode pad over a substrate;
forming a solder bump over said electrode pad, at least part of a surface of said solder bump being covered with flux; and
exposing said solder bump to oxygen gas reactive therewith.

2. The method as claimed in claim 1, wherein said oxygen gas is ozone gas.

3. The method as claimed in claim 2, wherein said exposing the solder bump to the oxygen gas includes exposing said solder bump to said ozone gas for 20 seconds or longer.

4. The method as claimed in claim 3, wherein said exposing the solder bump to the oxygen gas includes exposing said solder bump to said ozone gas for 40 seconds or shorter.

5. The method as claimed in claim 1, wherein said exposing the solder bump to the oxygen gas includes irradiating said solder bump with oxygen-containing plasma.

6. The method as claimed in claim 1, wherein said exposing the solder bump to the oxygen gas includes forming an oxide film over said solder bump, and said method further comprising exposing said solder bump to reduction gas to reduce said oxide film, said exposing the solder bump to the gas being performed after said exposing the solder bump to the oxygen gas.

7. The method as claimed in claim 6, wherein said exposing the solder bump to the gas includes irradiating said solder bump with hydrogen plasma.

8. The method as claimed in claim 1, wherein
said forming the solder bump includes:
applying solder containing flux onto said electrode pad; and
forming said solder bump by melting said solder applied onto said electrode pad.

9. The method as claimed in claim 1, wherein
said forming the solder bump includes:
forming a solder-plate film over said electrode pad by a plating technique;
applying flux onto said solder-plate film; and
forming said solder bump by melting said solder-plate film to which said flux is applied.

10. A semiconductor manufacturing apparatus comprising:
a stage over which a substrate is placed, an electrode pad being formed over said substrate, flux-containing solder being applied onto said electrode pad;
a heating unit that melts said solder applied onto said electrode pad; and
an oxygen supply unit that supplies an oxygen gas reactive with a solder bump formed through melting of said solder.

11. The semiconductor manufacturing apparatus as claimed in claim 10, further comprising:
a reduction gas supply unit that supplies reduction gas for reducing an oxide film formed by said reactive oxygen gas.

12. The semiconductor manufacturing apparatus as claimed in claim 11, further comprising:
a plasma generating unit that generates plasma of said reduction gas.
